(19) United States
(12) Patent Application Publication
(10) Pub. No.: US 2026/0344487 A1
(43) Pub. Date: Oct. 29, 2026

(54) SEMICONDUCTOR DEVICE AND METHOD OF MANUFACTURING THE SAME

(71) Applicant: SUMITOMO ELECTRIC DEVICE INNOVATIONS, INC., Yokohama-shi (JP)

(72) Inventors: Hironobu YAMAMOTO, Yokohama-shi (JP); Takashi KITAWADA, Yokohama-shi (JP)

(73) Assignee: SUMITOMO ELECTRIC DEVICE INNOVATIONS, INC., Yokohama-shi (JP)

(21) Appl. No.: 19/657,669

(22) Filed: Apr. 24, 2026

(30) Foreign Application Priority Data
Apr. 28, 2025 (JP) 2025-074461
Jan. 22, 2026 (JP) 2026-008968

(51) Int. Cl. H10W 72/00; H10W 40/00; H10W 40/20; H10W 40/25; H10W 72/30; H10W 90/00; H10W 90/10

(52) U.S. Cl. CPC H10W 72/01365; H10W 40/03; H10W 40/242; H10W 40/255; H10W 72/01323; H10W 72/01361; H10W 72/07331; H10W 72/07352; H10W 72/323; H10W 72/332; H10W 72/334; H10W 72/352; H10W 72/365; H10W 90/10; H10W 90/733; H10W 90/736

(57) ABSTRACT

A method of manufacturing a semiconductor device includes applying a first metal paste to one surface of a package, heat-treating the first metal paste, applying a second metal paste to a heat-treated first metal paste, mounting a semiconductor chip on the second metal paste, and heat-treating the second metal paste after mounting the semiconductor chip.

### CROSS REFERENCE TO RELATED APPLICATIONS

This application claims priority based on Japanese Patent Applications No. 2025-074461 filed on Apr. 28, 2025 and No. 2026-008968 filed on Jan. 22, 2026, and the entire contents of the Japanese patent applications are incorporated herein by reference.

### FIELD

The present disclosure relates to a semiconductor device and a method of manufacturing the same.

### BACKGROUND

A semiconductor chip may be mounted on a package using a silver paste (for example, Japanese Unexamined Patent Application Publication No. 2009-177197).

### SUMMARY

A method of manufacturing a semiconductor device according to the present disclosure includes: applying a first metal paste to one surface of a package; heat-treating the first metal paste; applying a second metal paste to a heat-treated first metal paste; mounting a semiconductor chip on the second metal paste; and heat-treating the second metal paste after mounting the semiconductor chip.

### BRIEF DESCRIPTION OF DRAWINGS

FIG. 1 is a plan view illustrating a semiconductor device according to an embodiment.

FIG. 2 is a cross-sectional view illustrating the semiconductor device.

FIG. 3A is a plan view illustrating a method of manufacturing the semiconductor device.

FIG. 3B is a plan view illustrating a method of manufacturing the semiconductor device.

FIG. 3C is a plan view illustrating a method of manufacturing the semiconductor device.

FIG. 4A is a cross-sectional view illustrating the method of manufacturing the semiconductor device.

FIG. 4B is a cross-sectional view illustrating the method of manufacturing the semiconductor device.

FIG. 4C is a cross-sectional view illustrating the method of manufacturing the semiconductor device.

FIG. 4D is a cross-sectional view illustrating the method of manufacturing the semiconductor device.

FIG. 4E is a cross-sectional view illustrating the method of manufacturing the semiconductor device.

FIG. 5A is a diagram illustrating a metal paste.

FIG. 5B is a diagram illustrating a metal paste.

FIG. 6A is a cross-sectional view illustrating a method of manufacturing a semiconductor device according to a comparative example.

FIG. 6B is a cross-sectional view illustrating a method of manufacturing a semiconductor device according to a comparative example.

FIG. 6C is a cross-sectional view illustrating a method of manufacturing a semiconductor device according to a comparative example.

FIG. 7 is a plan view illustrating a semiconductor device according to a second embodiment.

FIG. 8 is a cross-sectional view illustrating the semiconductor device.

FIG. 9 is a cross-sectional view illustrating the semiconductor device.

FIG. 10 is a plan view illustrating a method of manufacturing the semiconductor device.

FIG. 11 is a plan view illustrating a method of manufacturing the semiconductor device.

FIG. 12 is a plan view illustrating a method of manufacturing the semiconductor device.

FIG. 13 is a plan view illustrating a semiconductor device according to a first modification.

FIG. 14 is a plan view illustrating a semiconductor device according to a second modification.

FIG. 15 is a plan view illustrating a semiconductor device according to a third modification.

### DETAILED DESCRIPTION OF EMBODIMENTS

A metal paste such as a sintered silver paste has a high thermal conductivity. The metal paste can be provided by printing, dispensing, or the like. In a mounting step, a metal paste having fluidity is applied and cured. Variation occurs in wet spreading of a metal paste. The heat dissipation is reduced in a portion where an amount of the metal paste is small. The surface tension of the metal paste may cause components to move and become misaligned. In addition, since the metal paste is thermally shrunk, it is difficult to control the thickness. It is therefore an object of the present disclosure to provide a semiconductor device and a method of manufacturing the same capable of achieving high heat dissipation and reducing positional misalignment and thickness variation.

### Details of Embodiments of the Present Disclosure

First, the contents of the embodiments of the present disclosure will be listed and explained.
(1) A method of manufacturing a semiconductor device according to the present disclosure includes: applying a first metal paste to one surface of a package; heat-treating the first metal paste; applying a second metal paste to a heat-treated first metal paste; mounting a semiconductor chip on the second metal paste; and heat-treating the second metal paste after mounting the semiconductor chip. Since the second metal paste spreads over the first metal paste, the heat dissipation is enhanced. The first metal paste is cured before mounting the semiconductor chip. In the mounting, the cured first metal paste is less likely to flow and shrink. The misalignment and the variations in thickness can be reduced.
(2) In the above (1), the first metal paste may be thicker than the second metal paste. Before the mounting, the thick first metal paste is cured. The thin second metal paste has a small amount of flow and shrinkage. The misalignment and the variations in thickness can be reduced.
(3) In the above (1) or (2), the first metal paste and the second metal paste may contain metal particles and a solvent, or the metal particles, the solvent, and a resin. The curing reaction proceeds by the heat-treating, and the metal particles approach each other or are integrated. The heat dissipation can be enhanced.
(4) In the above (3), the metal particles may be silver particles, copper particles, gold particles, or nickel particles. The heat dissipation can be enhanced.
(5) In the above (3) or (4), the solvent may contain an organic vehicle. The curing reaction proceeds by the heat-treating, and the first metal paste and the second metal paste shrink. Before the mounting, the thick first metal paste is cured. The misalignment and the variations in thickness can be reduced.
(6) In any one of the above (3) to (5), the resin may be an epoxy resin, a urethane resin, an acrylic resin, a silicone resin, a phenol resin, a polyester resin, or a polyamide resin. The curing reaction proceeds by the heat-treating, and the first metal paste and the second metal paste shrink. Before the mounting, the thick first metal paste is cured. The misalignment and the variations in thickness can be reduced.
(7) In any one of the above (1) to (6), a volume shrinkage rate of the first metal paste in the heat-treating the first metal paste may be 5% or more and 50% or less. Before the mounting, the thick first metal paste is cured. The misalignment and the variations in thickness can be reduced.
(8) In any one of the above (1) to (7), in the mounting the semiconductor chip, the semiconductor chip and the chip component may be mounted on the second metal paste. Since the second metal paste is thin, the flow amount is small. Misalignment of the semiconductor chip and the chip component is reduced, making them less likely to come into contact with each other.
(9) In any one of the above (1) to (8), in the heat-treating the first metal paste and the heat-treating the second metal paste, the first metal paste and the second metal paste may be cured to form a sintered metal layer from each of the first metal paste and the second metal paste. The curing reaction proceeds by the heat-treating, and the metal particles approach each other and are integrated. The heat dissipation can be enhanced.
(10) In any one of the above (1) to (9), the applying the first metal paste may be applying a plurality of the first metal pastes, the first metal paste may not be provided between the plurality of first metal pastes in the package, the applying the second metal paste may be applying the second metal paste so as to overlap the plurality of first metal pastes, and the mounting the semiconductor chip may be mounting the semiconductor chip on the second metal paste so as to overlap the plurality of first metal pastes. The first metal paste exerts a resistance force against the surface tension of the second metal paste. Therefore, the misalignment can be prevented.
(11) In the above (10), the applying the first metal paste may be applying the plurality of first metal pastes each having a dot shape. Since the first metal paste exerts a resistance force, the misalignment can be prevented.
(12) In the above (10), the applying of the first metal paste may be applying the plurality of first metal pastes each having a linear shape. Since the first metal paste exerts a resistance force, the misalignment can be prevented.
(13) In any one of the above (10) to (12), the heat-treating the first metal paste may be performed at a first temperature, and the heat-treating the second metal paste may be performed at a second temperature higher than the first temperature. Since the temporarily cured first metal paste exerts a resistance force, the misalignment can be prevented.
(14) A semiconductor device includes: a package; a metal paste layer provided on one surface of the package; and a semiconductor chip mounted on the package by the metal paste layer; wherein the metal paste layer includes a first metal paste layer provided on one surface of the package and a second metal paste layer provided on a surface of the first metal paste layer opposite to the package. The heat dissipation is enhanced. The misalignment and the variations in thickness can be reduced.
(15) In the above (14), the metal paste layer may include a plurality of first metal paste layers, the first metal paste layer may not be provided between the plurality of first metal paste layers in the package, the second metal paste layer may overlap the plurality of first metal paste layers, and the semiconductor chip may be mounted on the second metal paste layer so as to overlap the plurality of first metal paste layers. The misalignment can be prevented.
(16) In the above (14), each of the plurality of first metal paste layers may have a dot shape. The misalignment can be prevented.
(17) In the above (14), each of the plurality of first metal paste layers may have a linear shape. The misalignment can be prevented.

### DETAILS OF EMBODIMENT OF PRESENT DISCLOSURE

Specific examples of a semiconductor device according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

### Semiconductor Device

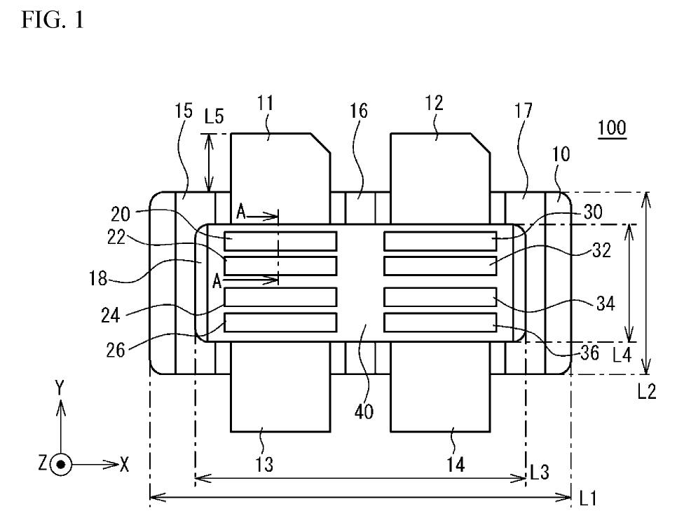

FIG. 1 is a plan view illustrating a semiconductor device 100 according to a first embodiment. The semiconductor device 100 includes a package 10 and a plurality of components. The number of components may be eight or less, or may be eight or more.

The package 10 is, for example, a metal plate, and is a copper (Cu) plate, a copper alloy plate, or a laminate of copper and a copper alloy. The surface of the package 10 may be bare or may be plated. The plating material is gold plating, silver plating, or the like. The package 10 includes a lead 11, a lead 12, a lead 13, a lead 14, a wall 15, a wall 16, and a wall 17. The leads and walls are also made of metal. The main surface of the package 10 is parallel to an XY plane. A Z-axis direction is a normal direction of a main surface of the package 10. The leads are parallel to an X-axis direction. The X-axis direction, a Y-axis direction, and the Z-axis direction are orthogonal to each other.

The wall 15, the wall 16, and the wall 17 are arranged in order in the X-axis direction. A cavity 18 is provided in a position surrounded by the wall 15, the wall 16, and the wall 17 in the package 10. The cavity 18 is parallel to the XY plane. The walls protrude in the Z-axis direction from the cavity 18. The cavity 18 is recessed in the Z-axis direction from the walls.

The leads 11 and 12 protrude upward from the cavity 18 in FIG. 1. The leads 13 and 14 protrude downward from the cavity 18 in FIG. 1. The leads 11 and 13 are located between the walls 15 and 16. The leads 12 and 14 are located between the walls 16 and 17.

A length L1 of the package 10 in the X-axis direction is, for example, 20 mm. A length L2 in the Y-axis direction is, for example, 10 mm. A length L3 of the cavity 18 in the X-axis direction is, for example, 16 mm. The length in the Y-axis direction is, for example, 6 mm. A protrusion amount L5 of the lead from the package 10 is, for example, 3 mm.

A component 20, a component 22, a component 24, a component 26, a component 30, a component 32, a component 34, and a component 36 are mounted in the cavity 18. The components 20, the component 22, the component 24, and the component 26 are arranged between the leads 11 and 13. The component 30, the component 32, the component 34, and the component 36 are arranged between the leads 12 and 14. The plurality of components are bonded to the package 10 by a sintered metal layer 40.

The component 22 and the component 32 are, for example, semiconductor chips, and include field effect transistors (FETs). The other components are chips including passive components such as capacitors. The components are spaced apart from each other. The interval between adjacent components is, for example, 0. 5 mm. The components are electrically connected to each other by a bonding wire (not illustrated). The component 20 is electrically connected to the lead 11 by a bonding wire (not illustrated). The component 26 is electrically connected to the lead 13 by a bonding wire (not illustrated). The component 30 is electrically connected to the lead 12 by a bonding wire (not illustrated). The component 36 is electrically connected to the lead 14 by a bonding wire (not illustrated).

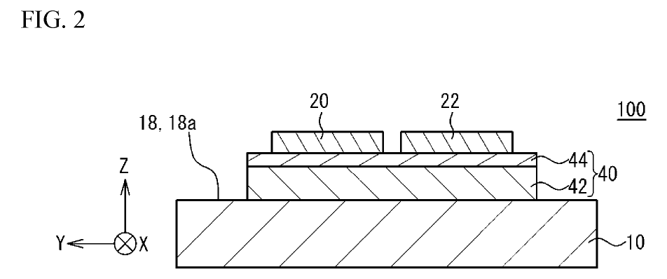

FIG. 2 is a cross-sectional view illustrating the semiconductor device 100, and illustrates a cross section along a line A-A of FIG. 1. A surface 18a of the cavity 18 is parallel to the XY plane. The sintered metal layer 40 is provided on the surface 18a. The sintered metal layer 40 is a cured metal paste layer, and includes a sintered metal layer 42 (cured first metal paste layer) and a sintered metal layer 44 (cured second metal paste layer). The sintered metal layer 42 is provided on the surface 18a. The sintered metal layer 44 is provided on the surface of the sintered metal layer 42. The sintered metal layer 42 is thicker than the sintered metal layer 44. The area of the sintered metal layer 42 is equal to or larger than the area of the sintered metal layer 44. For example, the sintered metal layer 44 may be provided on the entire upper surface of the sintered metal layer 42. The sintered metal layer 40 contains metal particles such as silver (Ag) particles, copper (Cu) particles, or nickel (Ni) particles, and is formed by heat treating a metal paste.

The component 22 and the component 32 are mounted on the surface 18a of the cavity 18, and are bonded to the surface 18a by the sintered metal layer 40. Other components are also fixed by the sintered metal layer 40.

Heat is generated when the components operate. The heat is dissipated to the outside through the sintered metal layer 40 and the package 10.

### Manufacturing Method

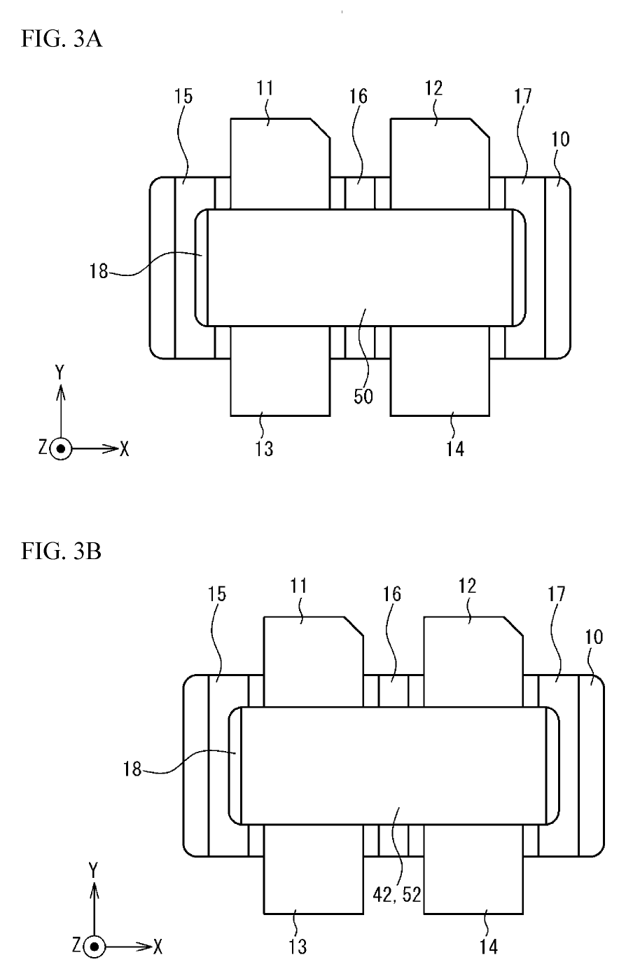

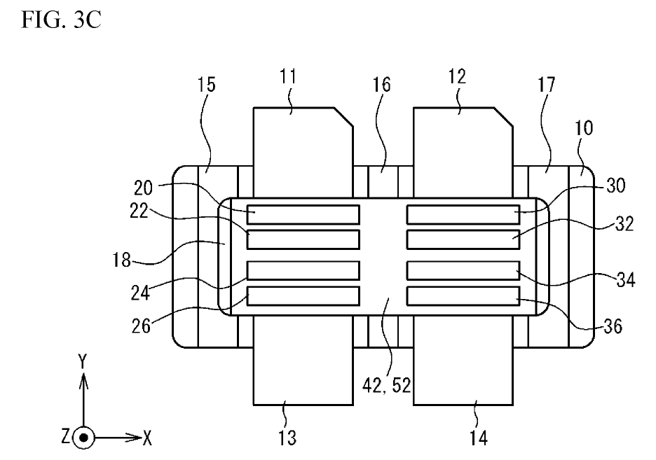

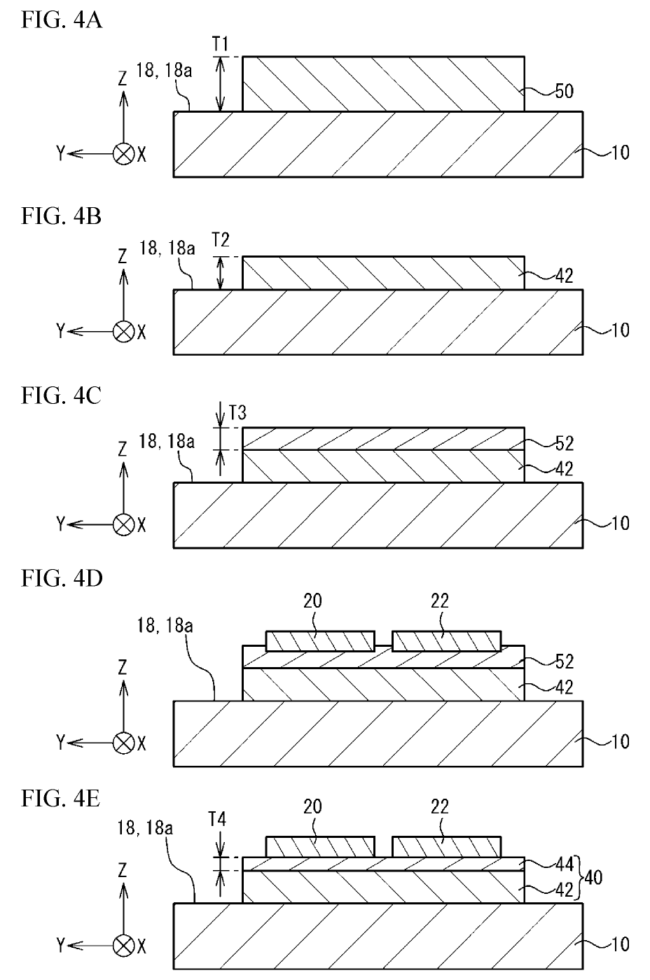

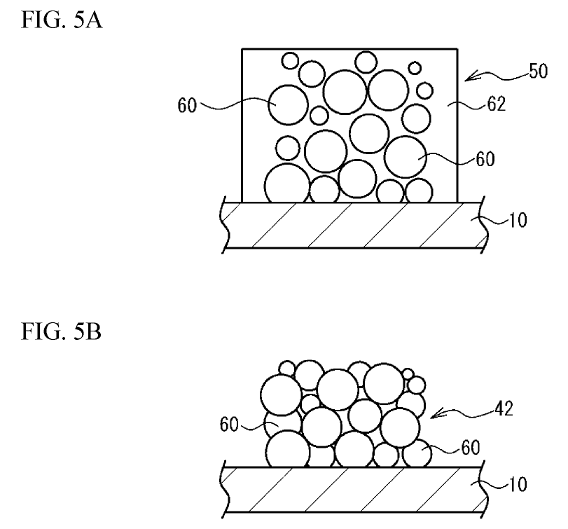

FIGS. 3A to 3C are plan views illustrating a method of manufacturing the semiconductor device 100. FIGS. 4A to 4E are cross-sectional views illustrating the method of manufacturing the semiconductor device 100.

As illustrated in FIGS. 3A and 4A, a sintered metal paste 50 (first metal paste) is applied to the surface 18a of the cavity 18 by dispensing, printing, or the like. The sintered metal paste 50 is, for example, a sintered Ag paste (sintered silver paste), and contains silver particles, a solvent, and a resin. The silver content is 80% or more. The solvent may be an organic vehicle. The resin is an epoxy resin or the like. A thickness T1 of the sintered metal paste 50 is, for example, 30 μm or more and 100 μm or less.

As illustrated in FIG. 4B, the sintered metal paste 50 is sintered by heat treatment to form the sintered metal layer 42. For example, the heating is performed at a temperature of 200 °C or higher for about 60 minutes. The curing reaction proceeds by the heat treatment, and the sintered metal paste 50 shrinks and cures. The volume shrinkage ratio is, for example, 5% or more and 50% or less. A thickness T2 of the sintered metal layer 42 after the heat treatment is smaller than the thickness T1 of the sintered metal paste 50 before the heat treatment.

As illustrated in FIGS. 3B and 4C, a sintered metal paste 52 (second metal paste) is applied to the surface of the sintered metal layer 42. The sintered metal paste 52 may be applied to the entire upper surface of the sintered metal layer 42 or may be applied to a part of the upper surface thereof. In the case of applying the sintered metal paste 52 to a part of the upper surface of the sintered metal layer 42, the area of the sintered metal paste 52 after the component is mounted is, for example, 50% or more or 80% or more of a component area (i.e., an area of the mounted component). The sintered metal paste 52 is, for example, a sintered Ag paste, similarly to the sintered metal paste 50. A thickness T3 of the sintered-metal paste 52 is, for example, 10 μm or more and 50 μm or less, and is thinner than the thickness T1 of the sintered metal paste 50.

As illustrated in FIGS. 3C and 4D, the components are pressed against the sintered metal paste 52 and mounted. As illustrated in FIG. 4E, the sintered metal paste 52 is cured by the heat treatment to form the sintered metal layer 44. For example, the heat treatment is performed at 200 °C or more for 60 minutes. Wire bonding is performed. The semiconductor device 100 is formed.

FIGS. 5A and 5B are diagrams illustrating the sintered metal paste. FIG. 5A illustrates the sintered metal paste 50 before curing. The sintered metal paste 50 contains metal particles 60 and a solvent 62, and may contain a resin. For example, the solvent 62 may contain a granular resin. The metal particles are, for example, a mixture of nano-sized metal particles and micro-sized metal particles. The particle diameter of the metal particles is, for example, several nm or more and 5 μm or less. FIG. 5B illustrates an example in which the sintered metal paste 50 is cured to form the sintered metal layer 42. The curing reaction proceeds and the volume decreases. The metal particles 60 are in contact with each other or integrated.

### Comparative Example

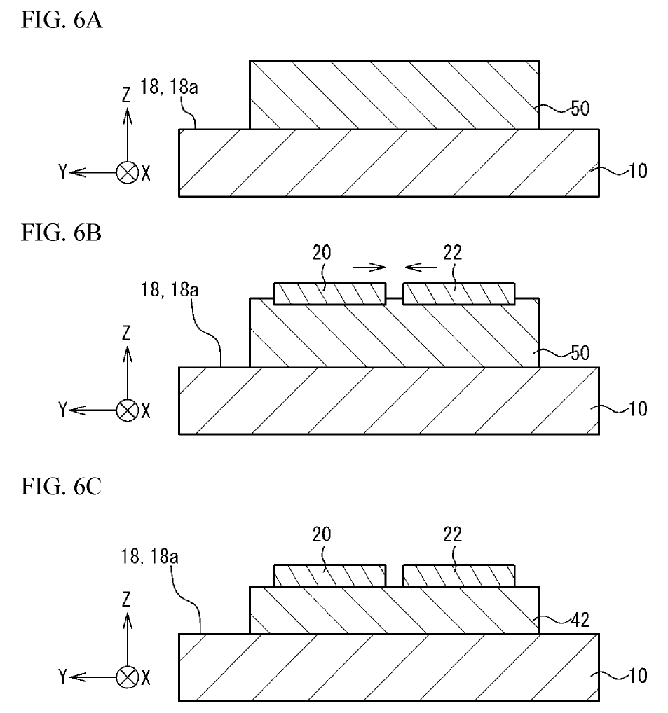

FIGS. 6A to 6C are cross-sectional views illustrating a method of manufacturing a semiconductor device according to a comparative example. The sintered metal paste 50 is applied to the surface 18a of the package 10. Before the heat treatment, the components are mounted on the sintered metal paste 50. After mounting, the heat treatment is performed to form the sintered metal layer 42.

Variations occur in the spread of the sintered metal paste 50, and the lower surfaces of the component 22 and the component 32 may have portions where the sintered metal paste 50 is not provided. In this case, variations in thermal resistance occur. That is, the heat dissipation of the portion where the sintered metal paste 50 is provided is high. The heat dissipation of the portion where the sintered metal paste 50 is not provided is low. In order to spread the sintered metal paste 50 over the lower surfaces of the component 22 and the component 32, the amount of the sintered metal paste 50 may be adjusted. However, the equipment and management of the process become complicated.

The sintered metal paste 50 may peel off due to a thermal stress. In order to reduce the thermal stress, the sintered metal paste 50 may be thickened. However, when the amount of the sintered metal paste 50 increases, the flow amount of the sintered Ag paste increases. After mounting the components, the surface tension of the sintered metal paste 50 causes the components to move within the plane as illustrated by arrows in FIG. 6B, resulting in positional misalignment. The sintered metal paste 50 shrinks due to the heat treatment. The thicker the sintered metal paste 50 is, the larger the amount of change in thickness due to the heat treatment is. Therefore, variations in thickness are more likely to occur.

According to the first embodiment, the sintered metal paste 50 is applied to the surface 18a of the package 10. The sintered metal paste 50 is cured by the heat treatment before mounting the components to form the sintered metal layer 42. The sintered metal paste 52 is applied to the sintered metal layer 42. The sintered metal paste 52 spreads over the sintered metal layer 42. The sintered metal layer 42 and the sintered metal paste 52 are provided in a wide range of the surface 18a. Variations in the heat dissipation are less likely to occur, and the heat dissipation can be improved.

After curing the sintered metal paste 50, the sintered metal paste 52 is provided, and the components are mounted on the sintered metal paste 52. After the components are mounted, the heat treatment is performed. The sintered metal paste 52 is cured to form the sintered metal layer 44. Since the sintered metal paste 50 is cured before mounting the components, the sintered metal paste 50 is less likely to flow or shrink. The change in the position of the component due to the flow of the sintered metal paste 52 is reduced. It is possible to prevent the misalignment of the components, the collision between the components, and the like.

The sintered metal paste 50 shrinks due to the heat treatment. The change in thickness due to shrinkage can be adjusted by applying the sintered metal paste 52. The change in thickness due to the shrinkage of the sintered metal paste 52 is smaller than the change in thickness of the sintered metal paste 50. Therefore, variations in thickness are less likely to occur. The thickness can be simply controlled, and for example, when the components are mounted, a load applied to a collet can be controlled to obtain an appropriate thickness. The sintered metal layer 40 has two sintered metal layers 42 and 44. The two layers can reduce the thermal stress and increase durability.

The sintered metal paste 50 is thicker than the sintered metal paste 52. The thick sintered metal paste 50 can reduce the thermal stress. The mechanical durability is improved. The amount of change in the thickness of the sintered metal paste 50 due to thermal shrinkage is larger than the amount of change in the thickness of the sintered metal paste 52. After mounting the components, the change in thickness due to the thermal shrinkage of the sintered metal paste 52 is small. Therefore, variations in the thickness are reduced. The amount of movement of the sintered metal paste 52 is smaller than the amount of movement of the sintered metal paste 50. Therefore, the misalignment of the components is less likely to occur.

The sintered metal paste 50 and the sintered metal paste 52 are, for example, a sintered Ag paste or a sintered Cu paste. The sintered metal paste 50 and the sintered metal paste 52 may contain metal particles and a solvent, may contain metal particles and a resin, or may contain metal particles, a solvent, and a resin. The curing reaction proceeds by heating to, for example, several hundred degrees in the heat treatment. The sintered metal paste is cured, and the metal particles form a sintered metal layer. Since Ag and Cu have low thermal resistance, the heat dissipation is improved. A metal paste other than the sintered Ag paste and the sintered Cu paste may be used, and for example, a sintered Ni paste containing nickel (Ni) particles may be used.

As the curing reaction proceeds, the volume of the sintered metal paste shrinks. A volume shrinkage ratio is, for example, 5% or more and 50% or less. The heat treatment of the thick sintered metal paste 50 is performed before mounting the components. When the heat treatment of the sintered metal paste 52 is performed after mounting the components, the sintered metal paste 52 shrinks. Since the sintered metal paste 52 is thin, the amount of change in thickness is also small. Variations in the thickness are reduced. The solvent is an organic solvent, such as an organic vehicle. The resin is an epoxy resin, a urethane resin, an acrylic resin, a silicone resin, a phenol resin, a polyester resin, a polyamide resin, or the like.

The sintered metal paste 50 and the sintered metal paste 52 may be the same type of metal paste. The sintered metal paste 50 and the sintered metal paste 52 may be different types of metal pastes.

The components mounted on the package 10 include a semiconductor chip and a chip component. Since the sintered metal paste 52 is thin, the flow amount is small. The misalignment of the plurality of components is reduced, and the components are less likely to come into contact with each other.

The package 10 is made of metal, and is formed of, for example, copper, a copper alloy, or a laminate of copper and a copper alloy. The sintered metal layer 40 is in contact with the package 10. Heat can be released from the sintered metal layer 40 and the package 10. Stress may be generated due to a difference in linear expansion coefficient between the package 10 and the sintered metal layer 40. Since the sintered metal layer 40 includes the thick sintered metal layer 42, the stress can be reduced.

The heat treatment of the sintered metal paste 50 is performed before applying the sintered metal paste 52. In this heat treatment, the sintered metal paste 50 may be completely cured or may be incompletely cured. The sintered metal paste 50 may be incompletely cured by the first heat treatment, and the sintered metal paste 50 and the sintered metal paste 52 may be completely cured by the second heat treatment.

### Second Embodiment

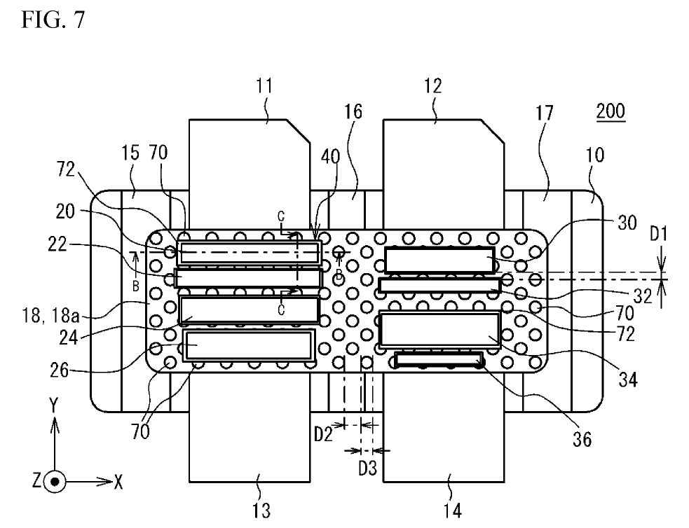

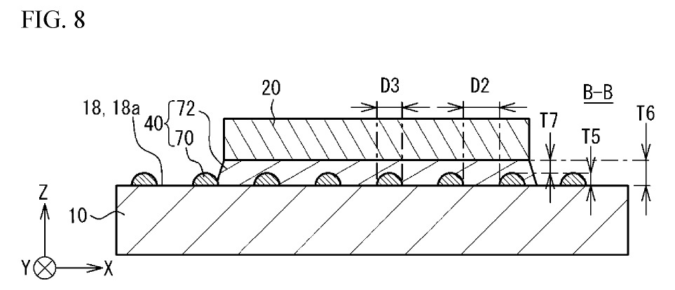

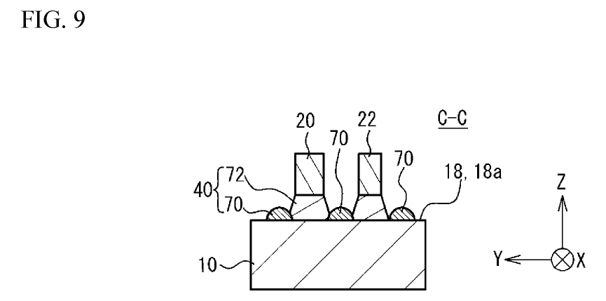

FIG. 7 is a plan view illustrating a semiconductor device 200 according to a second embodiment. FIGS. 8 and 9 are cross-sectional views illustrating the semiconductor device 200. FIG. 8 illustrates a cross-section along a line B-B in FIG. 7. FIG. 9 illustrates a cross-sectional view along a line C-C of FIG. 7. The description of the same configuration as that of the first embodiment will be omitted. The sintered metal layer 40 is provided on the surface 18a of the cavity 18. The sintered metal layer 40 includes a plurality of sintered metal layers 70 and a sintered metal layer 72.

As illustrated in FIG. 7, the sintered metal layers 70 are provided in a dot shape in the surface 18a. The planar shape of the sintered metal layer 70 is, for example, circular. The plurality of sintered metal layers 70 are arranged periodically along the X-axis direction and the Y-axis direction. The plurality of sintered metal layers 70 are spaced apart from each other and are discretely provided. The sintered metal layer 70 is not provided in a portion between the sintered metal layers 70 in the surface 18a of the cavity 18.

The planar shape of the sintered metal layer 72 is, for example, rectangular. The longitudinal direction of the sintered metal layer 72 is the X-axis direction, and the lateral direction is the Y-axis direction. The sintered metal layer 72 is provided so as to overlap the plurality of sintered metal layers 70 in the X-axis direction. The component 20 is provided on the sintered metal layer 72 so as to overlap the plurality of sintered metal layers 70. Other components are also provided on the sintered metal layer 72 so as to overlap the plurality of sintered metal layers 70. The component and the sintered metal layer 70 may overlap the plurality of sintered metal layers 70 in the Y-axis direction. The sintered metal layer 70 is exposed outside the sintered metal layer 72.

As illustrated in FIGS. 8 and 9, the sintered metal layer 70 has, for example, a dome shape and has a spherical surface. The sintered metal layer 72 covers the plurality of sintered metal layers 70, is provided between two adjacent sintered metal layers 70, and is also provided between the sintered metal layer 70 and the component.

An interval D1 between the components is, for example, 0.1 mm or less. An interval D2 between two adjacent sintered metal layers 70 is, for example, 0.2 mm or more and 0.5 mm. A diameter D3 of the sintered metal layer 70 is, for example, 0.3 mm or more and 0.5 mm or less, and may be 0.4 mm. A thickness T5 of the sintered metal layer 70 is, for example, 0.03 mm or more and 0.05 mm or less. The sintered metal layer 72 is thicker between the surface 18a and the bottom surface of the component and thinner between the sintered metal layer 70 and the bottom surface of the component. A thickness T6 of the sintered metal layer 72 between the surface 18a and the bottom surface of the component is, for example, 0.05 mm. A thickness T7 of the sintered metal layer 72 between the sintered metal layer 70 and the bottom surface of the component is, for example, 0.02 mm. The area of the sintered metal layer 70 overlapping the components may be 30% or more and 50% or less of the area of the components in the XY plane.

In the example of FIG. 7, eight components and eight sintered metal layers 72 are provided on the surface 18a. One sintered metal layer 72 is provided for one component. The sintered metal layer 70 and the sintered metal layer 72 contain metal particles such as silver (Ag) particles, copper (Cu) particles, or nickel (Ni) particles, and are formed by heat treating a metal paste.

### Manufacturing Method

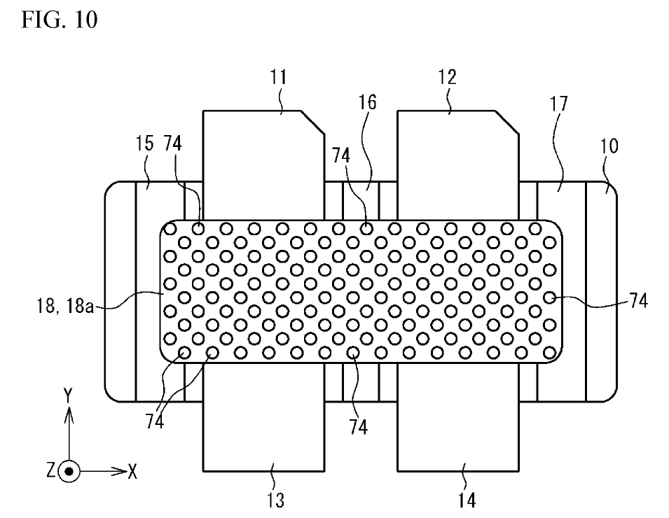

FIGS. 10 to 12 are plan views illustrating the method of manufacturing the semiconductor device 200. As illustrated in FIG. 10, a plurality of sintered metal pastes 74 (first metal pastes) are applied to the surface 18a of the cavity 18 by dispensing, printing, and the like. The sintered metal paste 74 is, for example, a pressureless sintering type sintered silver paste. The silver content of the sintered metal paste 74 is, for example, 80% or more. As illustrated in FIG. 10, the plurality of sintered metal pastes 74 are dot-shaped and are periodically arranged along the X axis and the Y axis. The diameter of the dot is, for example, 0.4 mm. The thickness of the dot is, for example, 0.03 mm or more and 0.05 mm or less. The distances between the dots are, for example, 0.2 mm and more and 0.5 mm or less.

The sintered metal paste 74 is sintered by heat treatment. This heat treatment is performed, for example, at a temperature (first temperature) of 100 °C for 30 minutes. The sintered metal paste 74 is not completely cured but is temporarily cured.

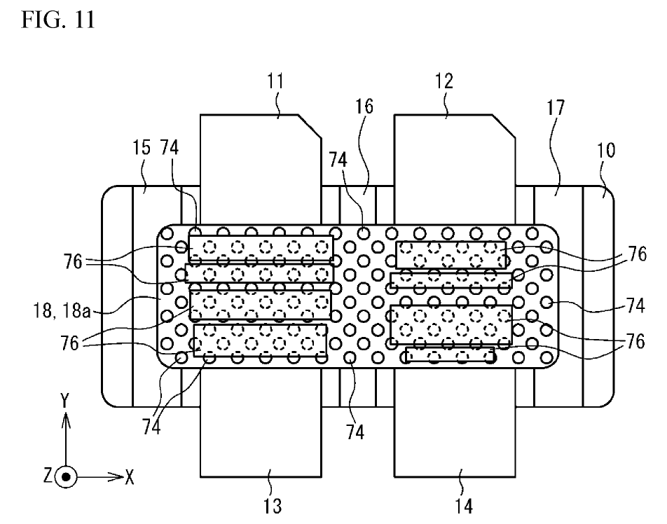

As illustrated in FIG. 11, a sintered metal paste 76 (second metal paste) is applied to the sintered metal paste 74. The sintered metal paste 76 is provided so as to straddle the plurality of sintered metal pastes 74. The same number of sintered metal pastes 76 as the number of components to be arranged are provided. In this example, eight sintered metal pastes 76 are applied. The sintered metal paste 74 is exposed at the position where the sintered metal paste 76 is not applied.

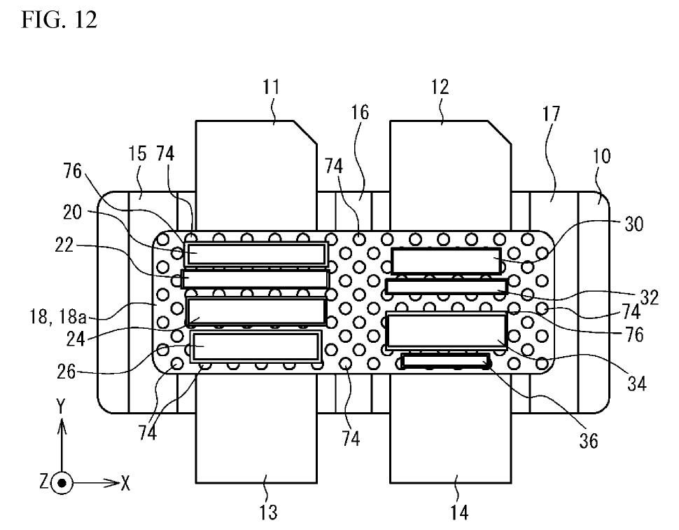

As illustrated in FIG. 12, the plurality of components are mounted with the sintered metal paste 76. The sintered metal paste 74 and the sintered metal paste 76 are completely cured by the heat treatment. This heat treatment is performed, for example, at a temperature (second temperature) of 200 °C for 60 minutes. The sintered metal paste 74 is cured to form the sintered metal layer 70. The sintered metal paste 76 is cured to form the sintered metal layer 72.

According to the second embodiment, the dot-shaped sintered metal paste 74 is applied to the surface 18a of the cavity 18, and the heat treatment is performed. The sintered metal paste 76 is applied so as to overlap the plurality of sintered metal pastes 74. The components are mounted on the sintered metal paste 76 so as to overlap the plurality of sintered metal pastes 74.

The sintered metal paste 76 before curing is likely to flow due to the surface tension. According to the second embodiment, the dot-shaped sintered metal paste 74 is provided below the sintered metal paste 76. The sintered metal paste 74 exerts a resistance force against the surface tension of the sintered metal paste 76. The sintered metal paste 74 is, for example, dome-shaped and has a spherical surface. The contact area between the sintered metal paste 74 and the sintered metal paste 76 increases. The increased area allows the sintered metal paste 74 to exert a large resistance force. The sintered metal paste 76 is thinner between the sintered metal paste 74 and the component than in a portion where the sintered metal paste 74 is not provided. The thinner the sintered metal paste 76, the greater the resistance to flow of the sintered metal paste 76. In this way, the resistance force increases, and thus it is possible to prevent the misalignment of the component due to the flow of the sintered metal paste 76.

Since the amount of misalignment is reduced, the components are less likely to collide with each other. The distance between the components can be reduced to, for example, 0. 1mm or less. By reducing the distance between the components, the packaging density can be increased and the performance of the semiconductor device 200 can be improved. Since the components are less likely to move, the sintered metal paste 76 is not pushed up between the components. The sintered metal paste 76 can be prevented from creeping up to the upper surfaces of the components.

Since there is a difference in linear expansion coefficient between the component and the package 10, a stress is generated due to temperature changes. By making the metal paste thin, the amount of flow is reduced, and the component is less likely to be misaligned. However, the thin metal paste may be broken by the stress. According to the second embodiment, the heat treatment is performed after applying the sintered metal paste 76. By this heat treatment, the sintered metal paste 74 and the sintered metal paste 76 are completely cured to form the sintered metal layer 40. The thickness of the sintered metal layer 40 is, for example, about the same as that of the first embodiment. The thickness of the sintered metal layer 40 can be maintained regardless of the shape of the sintered metal paste 74. The thick sintered metal layer 40 has high strength and can prevent breakage.

After applying the sintered metal paste 74 and before applying the sintered metal paste 76, the heat treatment is performed at 100 °C for 30 minutes, for example. The sintered metal paste 74 is temporarily cured by the heat treatment. The temporarily sintered metal paste 74 exerts a resistance force against the surface tension of the sintered metal paste 76. In addition, the volume of the temporarily cured sintered metal paste 74 is larger than the volume after the cured sintered metal paste 74 is completely cured. The sintered metal paste 76 becomes thin between the sintered metal paste 74 and the component, and is less likely to flow. The component is less likely to be misaligned.

The second heat treatment is performed at a temperature higher than that of the first heat treatment. The sintered metal paste 74 and the sintered metal paste 76 are completely cured by the second heat treatment. Both the sintered metal paste 74 and the sintered metal paste 76 are thermally shrunk by this heat treatment. A gap is less likely to be generated between the sintered metal paste 74 and the sintered metal paste 76.

The sintered metal paste 76 is applied to the temporarily cured sintered metal paste 74. The sintered metal paste 76 covers the sintered metal paste 74 and is filled between the plurality of sintered metal pastes 74. The total thickness of the metal paste becomes uniform in the in-plane direction. The sintered metal paste 74 may be completely cured before applying the sintered metal paste 76.

The sintered metal paste 74 and the sintered metal paste 76 may be the same type of metal paste or different types of metal pastes. The sintered metal paste 74 and the sintered metal paste 76 may be the sintered Ag paste. The sintered metal paste 74 may be the sintered Cu paste, and the sintered metal paste 76 may be the sintered Ag paste. The sintered metal paste 74 may be the sintered Ag paste, and the sintered metal paste 76 may be the sintered Cu paste. A metal paste containing a metal other than Ag and Cu may be used.

### First Modification

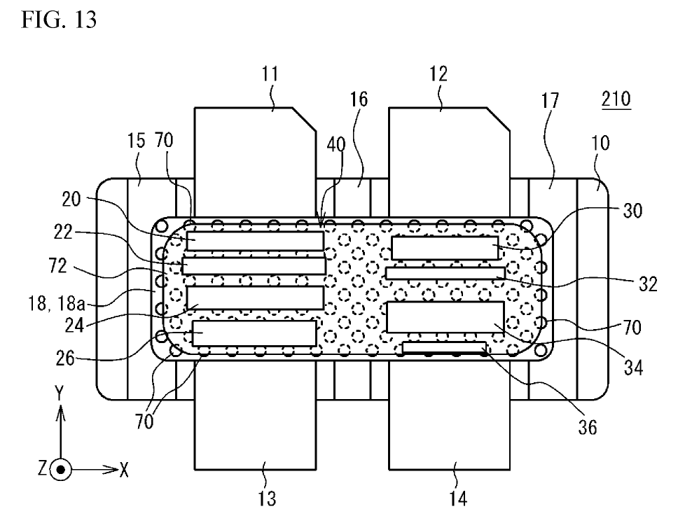

FIG. 13 is a plan view illustrating a semiconductor device 210 according to a first modification. The description of the same configuration as that of the first embodiment or the second embodiment will be omitted.

The sintered metal layer 40 includes the plurality of sintered metal layers 70 and one sintered metal layer 72. The sintered metal layer 72 is provided so as to overlap the plurality of sintered metal layers 70. The plurality of components are provided on the sintered metal layer 72 and fixed to the cavity 18 by the sintered metal layer 72.

### Manufacturing Method

The plurality of dot-shaped sintered metal pastes 74 are provided and heat-treated. After the heat treatment, one sintered metal paste 76 is applied so as to overlap the plurality of sintered metal pastes 74. The plurality of components are mounted on the sintered metal paste 76. The sintered metal paste is cured by the heat treatment.

According to the first modification, the sintered metal paste 76 overlaps the plurality of sintered metal pastes 74. The sintered metal pastes 74 exert the resistance force against the surface tension of the sintered metal paste 76. In addition, the sintered metal paste 76 becomes thinner between the sintered metal pastes 74 and the components, and the resistance force increases. The misalignment can be prevented.

### Second Modification

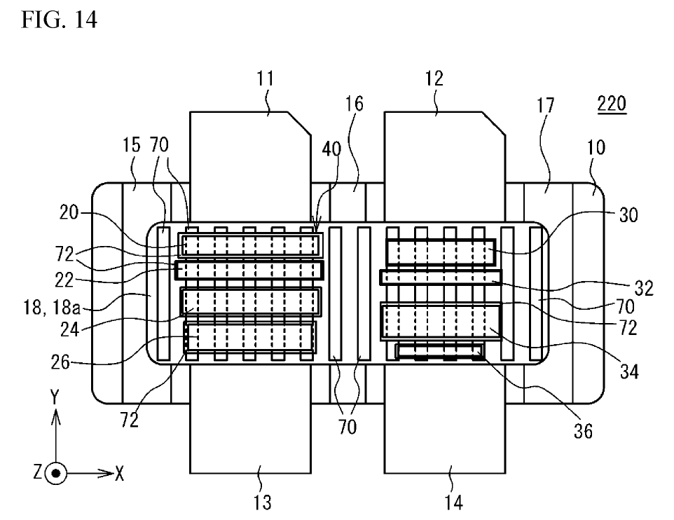

FIG. 14 is a plan view illustrating a semiconductor device 220 according to a second modification. The description of the same configuration as that of the first embodiment or the second embodiment will be omitted.

The sintered metal layer 70 has a linear shape parallel to the Y axis. The plurality of sintered metal layers 70 are separated from each other, and the plurality of sintered metal layers 70 are periodically arranged along the X-axis to form stripes. The sintered metal layers 72 and the components are provided so as to overlap the plurality of sintered metal layers 70 in the X-axis direction, for example. The cross section is the same as that of FIG. 8.

### Manufacturing Method

The plurality of linear sintered metal pastes 74 are provided and heat-treated. After the heat treatment, the sintered metal paste 76 is applied so as to overlap the plurality of sintered metal pastes 74. The plurality of components are mounted on the sintered metal paste 76. The sintered metal paste is cured by the heat treatment.

According to the second modification, the sintered metal paste 76 overlaps the plurality of sintered metal pastes 74. The sintered metal pastes 74 exert the resistance force against the surface tension of the sintered metal paste 76. In addition, the sintered metal paste 76 becomes thinner between the sintered metal pastes 74 and the components, and the resistance force increases. The misalignment can be prevented.

### Third Modification

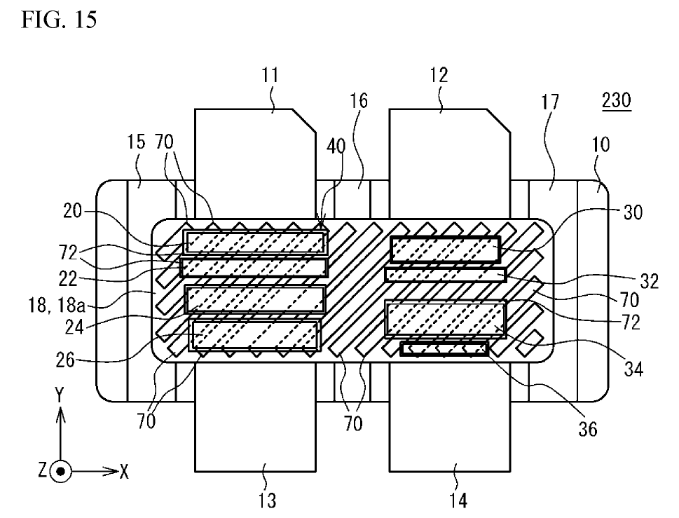

FIG. 15 is a plan view illustrating a semiconductor device 230 according to a third modification. The description of the same configuration as that of the first embodiment or the second embodiment will be omitted.

The sintered metal layer 70 has a linear shape and is inclined with respect to the X axis and the Y axis. The plurality of sintered metal layers 70 are spaced apart from each other and arranged periodically. The sintered metal layers 72 and the components are provided so as to overlap the plurality of sintered metal layers 70 in the X-axis direction, for example.

### Manufacturing Method

The plurality of linear sintered metal pastes 74 are provided and heat-treated. After the heat treatment, the sintered metal paste 76 is applied so as to overlap the plurality of sintered metal pastes 74. The plurality of components are mounted on the sintered metal paste 76. The sintered metal paste is cured by the heat treatment.

According to the third modification, the sintered metal paste 76 overlaps the plurality of sintered metal pastes 74. The sintered metal pastes 74 exert the resistance force against the surface tension of the sintered metal paste 76. In addition, the sintered metal paste 76 becomes thinner between the sintered metal pastes 74 and the components, and the resistance force increases. The misalignment can be prevented.

The sintered metal layer 70 may have a linear shape, may include a polygonal line, or may include a curved line. The sintered metal layer 70 may have a linear shape or a dot shape. The sintered metal layers 72 and the components may overlap the plurality of sintered metal layers 70.

Although the embodiments of the present disclosure have been described in detail, the present disclosure is not limited to these specific embodiments, and various modifications and changes can be made within the scope of the gist of the present disclosure described in the claims.

1. A method of manufacturing a semiconductor device comprising:
applying a first metal paste to one surface of a package;
heat-treating the first metal paste;
applying a second metal paste to a heat-treated first metal paste;
mounting a semiconductor chip on the second metal paste; and
heat-treating the second metal paste after mounting the semiconductor chip.

2. The method of manufacturing a semiconductor device according to claim 1, wherein
the first metal paste is thicker than the second metal paste.

3. The method of manufacturing a semiconductor device according to claim 1, wherein
the first metal paste and the second metal paste contain metal particles and a solvent, or the metal particles, the solvent, and a resin.

4. The method of manufacturing a semiconductor device according to claim 3, wherein
the metal particles are silver particles, copper particles, gold particles, or nickel particles.

5. The method of manufacturing a semiconductor device according to claim 3, wherein the solvent contains an organic vehicle.

6. The method of manufacturing a semiconductor device according to claim 3, wherein
the resin is an epoxy resin, a urethane resin, an acrylic resin, a silicone resin, a phenol resin, a polyester resin, or a polyamide resin.

7. The method of manufacturing a semiconductor device according to claim 1, wherein
a volume shrinkage rate of the first metal paste in the heat-treating the first metal paste is 5% or more and 50% or less.

8. The method of manufacturing a semiconductor device according to claim 1, wherein
in the mounting the semiconductor chip, the semiconductor chip and the chip component are mounted on the second metal paste.

9. The method of manufacturing a semiconductor device according to claim 1, wherein
in the heat-treating the first metal paste and the heat-treating the second metal paste, the first metal paste and the second metal paste are cured to form a sintered metal layer from each of the first metal paste and the second metal paste.

10. The method of manufacturing a semiconductor device according to claim 1, wherein
the applying the first metal paste is applying a plurality of the first metal pastes,
the first metal paste is not provided between the plurality of first metal pastes in the package,
the applying the second metal paste is applying the second metal paste so as to overlap the plurality of first metal pastes, and
the mounting the semiconductor chip is mounting the semiconductor chip on the second metal paste so as to overlap the plurality of first metal pastes.

11. The method of manufacturing a semiconductor device according to claim 10, wherein
the applying the first metal paste is applying the plurality of first metal pastes each having a dot shape.

12. The method of manufacturing a semiconductor device according to claim 10, wherein
the applying of the first metal paste is applying the plurality of first metal pastes each having a linear shape.

13. The method of manufacturing a semiconductor device according to claim 10, wherein
the heat-treating the first metal paste is performed at a first temperature, and
the heat-treating the second metal paste is performed at a second temperature higher than the first temperature.

14. A semiconductor device comprising:
a package;
a metal paste layer provided on one surface of the package; and
a semiconductor chip mounted on the package by the metal paste layer;
wherein the metal paste layer includes a first metal paste layer provided on one surface of the package and a second metal paste layer provided on a surface of the first metal paste layer opposite to the package.

15. The semiconductor device according to claim 14, wherein
the metal paste layer includes a plurality of first metal paste layers,
the first metal paste layer is not provided between the plurality of first metal paste layers in the package,
the second metal paste layer overlaps the plurality of first metal paste layers, and
the semiconductor chip is mounted on the second metal paste layer so as to overlap the plurality of first metal paste layers.

16. The semiconductor device according to claim 15, wherein
each of the plurality of first metal paste layers has a dot shape.

17. The semiconductor device according to claim 15, wherein
each of the plurality of first metal paste layers has a linear shape.
